(19) United States
(12) Patent Application Publication
(10) Pub. No.: US 2011/0298335 A1
(43) Pub. Date: Dec. 8, 2011

(54) ELECTROMECHANICAL TRANSDUCER HAVING A POLYISOCYANATE-BASED POLYMER ELEMENT

(75) Inventors: Werner Jenninger, Koln (DE); Sebastian Dörr, Dusseldorf (DE); Joachim Wagner, Koln (DE); Burkhard Köhler, Zierenberg (DE); Heike Heckroth, Odenthal (DE); Mathias Matner, Neuss (DE)

(73) Assignee: BAYER MATERIALSCIENCE AG, LEVERKUSEN (DE)

(21) Appl. No.: 13/056,178

(22) PCT Filed: Jul. 17, 2009
(86) PCT No.: PCT/EP09/05212

§ 371 Date: Mar. 4, 2011

(30) Foreign Application Priority Data
Jul. 30, 2008 (DE) 08013648.4

(51) Int. Cl. H01L 41/193; H02N 2/18; H01L 41/04

(52) U.S. Cl. 310/338; 310/311; 310/328; 310/339

(57) ABSTRACT

The present invention relates to an electromechanical transducer, in particular an electromechanical sensor, actuator and/or generator, which exhibits a polymer element that is obtainable from a reaction mixture comprising a polyisocyanate or a polyisocyanate prepolymer or a mixture thereof and a compound with at least two isocyanate-reactive amino groups. Moreover, the present invention relates to a process for producing an electromechanical transducer of such a type and also to the use of a polymer element of such a type as an electromechanical element. Furthermore, the present invention relates to an electronic and/or electrical apparatus that includes an electromechanical transducer according to the invention, and also to the use of an electromechanical transducer according to the invention in an electronic and/or electrical apparatus.

The present invention relates to an electromechanical transducer, in particular an electromechanical sensor, actuator and/or generator, which exhibits a polymer element that is obtainable from a reaction mixture comprising a polyisocyanate or a polyisocyanate prepolymer or a mixture thereof and a compound with at least two isocyanate-reactive amino groups. Moreover, the present invention relates to a process for producing an electromechanical transducer of such a type, and also to the use of a polymer element of such a type as an actuator, sensor and/or generator. Furthermore, the present invention relates to an electronic and/or electrical apparatus that includes an electromechanical transducer according to the invention, and also to the use of an electromechanical transducer according to the invention in an electronic and/or electrical apparatus.

An electromechanical transducer converts electrical energy into mechanical energy and vice versa. Electromagnetic transducers can therefore be employed as sensors, actuators and/or generators.

The fundamental structure, of such a transducer is based on a layer of an electroactive polymer that is coated with electrodes on both sides. In this connection the expression ‘electroactive polymer’ is understood to mean a polymer that changes its volume and/or its shape in a manner depending on a voltage applied thereto, and/or that is able to generate a voltage as a result of a change of volume and/or shape.

WO 01/06575 A1 discloses that these properties may be exhibited by, for example, silicone elastomers, acrylic elastomers, polyurethanes, thermoplastic elastomers, copolymers including polytetrafluorethylene, fluoroelastomers, and polymers including silicone groups and acrylic groups.

Furthermore, from EP 1 081 171 A2 and DE-A 102 46 708 A1 it is known that polyurethane prepolymers can be crosslinked by means of aspartic acid esters.

However, conventional polymers that are employed in electromechanical transducers frequently exhibit poor mechanical and other properties, in particular adverse strain properties, a slight insulating effect, in particular low breakdown field strengths and high electrical conductivities, poor processability and high material costs. In particular, a combination of the desired property features cannot be achieved in one material by means of polymers, for example silicones, that are conventionally employed in electromechanical transducers.

The object of the present invention was therefore to make available an electromechanical transducer that overcomes the drawbacks of known electromechanical transducers.

Within the scope of the present invention it has been found that this object is achieved by a polymer element that is obtainable from a reaction mixture comprising a polyisocyanate or a polyisocyanate prepolymer or a mixture thereof and a compound with at least two isocyanate-reactive amino groups, in particular an amino-functional aspartic acid ester. In this connection, within the scope of the present invention the terms ‘polyisocyanate’ and ‘polyisocyanate prepolymer’ are understood to mean a compound that exhibits at least two free isocyanate groups. In other words, the terms ‘polyisocyanate’ and ‘polyisocyanate prepolymer’ are understood to mean a compound that is at least doubly isocyanate-functional.

The present invention therefore provides an electromechanical transducer that exhibits at least two electrodes and at least one polymer element, the polymer element being arranged between two electrodes and, in particular, contacting at least one of the electrodes, and the polymer element being obtainable in accordance with the invention from a, for example, film-forming reaction mixture comprising the following components

A) a polyisocyanate or a polyisocyanate prepolymer or a mixture thereof, and
B) a compound with at least two isocyanate-reactive-amino groups.

If a mechanical load is exerted on a transducer of such a type, the transducer is deformed, for example along its thickness, and a strong electrical signal can be detected at the electrodes. Hence mechanical energy is converted into electrical energy. The transducer according to the invention can consequently be employed both as a generator and as a sensor.

By utilising the opposite effect, namely the conversion of electrical energy into mechanical energy, the transducer according to the invention may, on the other hand, serve equally as an actuator.

Within the scope of one embodiment of the present invention, the polymer element is arranged between two electrodes in such a manner that the latter adjoin the polymer element on opposite sides thereof. For example, the polymer element may have been coated with electrodes on both sides.

The present invention further provides a process for producing an electromechanical transducer according to the invention, in which
at least two electrodes are provided, and
a polymer element is provided by conversion of a reaction mixture comprising the following components
   A) a polyisocyanate or a polyisocyanate prepolymer or a mixture thereof, and
   B) a compound with at least two isocyanate-reactive amino groups, and
the polymer element is arranged between two electrodes.

In particular in this connection, the polymer element may be arranged between two electrodes in such a manner that the polymer element contacts at least one of the electrodes.

Within the scope of a preferred embodiment of the process according to the invention, the polymer element is provided by applying the reaction mixture onto at least one of the electrodes. This can be effected, for example, by knife coating, brushing, casting, centrifuging, spraying or extrusion. However, within the scope of the present invention it is equally possible to produce the electrodes and the polymer element in separate steps and to assemble them subsequently.

Within the scope of a preferred embodiment of the process according to the invention, the reaction mixture is dried and/or annealed. In this connection, drying may be effected within a temperature range from ≧0° C. to ≦200° C., for example for ≧0.1 min to ≦48 h, in particular for ≧6 h to ≦18 h. Annealing may, for example, be effected within a temperature range from ≧80° C. to ≦250° C., for example for ≧0.1 min to ≦24 h.

The present invention further provides the use of a polymer element that is obtainable from a reaction mixture comprising the following components

A) a polyisocyanate or a polyisocyanate prepolymer or a mixture thereof, and
B) a compound with at least two isocyanate-reactive amino groups,
as an electromechanical element, for example as a sensor, actuator and/or generator, in particular as an electromechanical element in a sensor, actuator and/or generator.

The present invention further provides an electronic and/or electrical apparatus, in particular a module, automatic machine, instrument or a component, including an electromechanical transducer according to the invention.

Furthermore, the present invention relates to the use of an electromechanical transducer according to the invention in an electronic and/or electrical apparatus, in particular in a module, automatic machine, instrument or in a component.

Within the scope of the present invention, the polymer element may be a polymer layer, in particular a polymer film, a polymer sheet or a polymer coating. For example, the polymer layer may exhibit a layer thickness from ≧0.1 μm to ≦1500 μm, for example from ≧1 μm to ≦5.00 μm, in particular from ≧5 μm to ≦200 μm, preferentially from ≧5 μm to ≦100 μm.

### Component A)

Within the scope of the present invention, component A) may in principle be a polyisocyanate or a polyisocyanate prepolymer or a mixture thereof. For example, component A) may be a polyisocyanate containing isocyanurate groups and/or urethane groups or a polyisocyanate prepolymer containing isocyanurate groups and/or urethane groups, or a mixture thereof.

Suitable as polyisocyanate A) are, for example, 1,4-butylene diisocyanate, 1,6-hexamethylene diisocyanate (HDI), isophorone diisocyanate (IPDI), 2,2,4 and/or 2,4,4-trimethylhexamethylene diisocyanate, the isomeric bis(4,4′-isocyanatocyclohexyl)methanes or mixtures thereof with arbitrary isomer content, 1,4-cyclohexylene diisocyanate, 4-isocyanatomethyl-1,8-octane diisocyanate (nonane triisocyanate), 1,4-phenylene diisocyanate, 2,4- and/or 2,6-toluoylene diisocyanate, 1,5-naphthylene diisocyanate, 2,2′- and/or 2,4′- and/or 4,4′-diphenylmethane diisocyanate, 1,3- and/or 1,4-bis(2-isocyanato-prop-2-yl)benzene (TMXDI), 1,3-bis(isocyanatomethyl)benzene (XDI), alkyl-2,6-diisocyanatohexanoates (lysine diisocyanates) with alkyl groups with 1 to 8 carbon atoms and also mixtures thereof.

In addition to the aforementioned polyisocyanates, modified diisocyanates that exhibit a functionality ≧2, with uretdione, isocyanurate, urethane, allophanate, biuret, iminooxadiazinedione or oxadiazinetrione structure, and also mixtures of these may also be employed proportionately.

It is preferably a question of polyisocyanates or polyisocyanate mixtures of the aforementioned type with exclusively aliphatically or cycloaliphatically bound isocyanate groups or mixtures of these and with a mean NCO functionality of the mixture from ≧2 to ≦4, preferably ≧2 to ≦2.6 and particularly preferably ≧2 to ≦2.4.

In particularly preferred manner, polyisocyanates based on hexamethylene diisocyanate, isophorone diisocyanate or the isomeric bis(4,4′-isocyanatocyclohexyl)methanes and also mixtures of the aforementioned diisocyanates are employed by way of component A).

The polyisocyanate prepolymers that can likewise be employed as component A) can be obtained by conversion of polyisocyanates with hydroxyl-functional, in particular polymeric, polyols, optionally with addition of catalysts and also auxiliary and added substances.

Hydroxy-functional, polymeric polyols may be, for example, polyester polyols, polyacrylate polyols, polyurethane polyols, polycarbonate polyols, polyether polyols, polyester-polyacrylate polyols, polyurethan-polyacrylate polyols, polyurethane-polyester polyols, polyurethane-polyether polyols, polyurethane-polycarbonate polyols and/or polyester-polycarbonate polyols. These may be employed individually or in arbitrary mixtures with one another for the purpose of producing the polyisocyanate prepolymer.

For the purpose of producing the polyisocyanate prepolymers, polyisocyanates, preferentially diisocyanates, can be converted with polyols in an NCO/OH ratio generally from ≧4:1 to ≦20:1, for example of 8:1. A proportion of unconverted polyisocyanates may subsequently be separated off. For this purpose, use may be made of thin-layer distillation, whereby products that are low in residual monomers, with residual-monomer contents of, for example, ≦1 percent by weight, preferably ≦0.5 percent by weight, particularly preferably ≦0.1 percent by weight, are obtained. The reaction temperature in this connection may amount to ≧20° C. to ≦120° C., preferably ≧60° C. to ≦100° C. Stabilisers such as benzoyl chloride, isophthaloyl chloride, dibutyl phosphate, 3-chloropropionic acid or methyl tosylate may optionally be added during production.

Suitable polyester polyols for producing the polyisocyanate prepolymers may be polycondensates formed from diols and also, optionally, triols and tetraols and dicarboxylic and also, optionally, tricarboxylic and tetracarboxylic acids or hydroxycarboxylic acids or lactones. Instead of the free polycarboxylic acids, the corresponding polycarboxylic acid anhydrides or corresponding polycarboxylic acid esters of lower alcohols may also be used for the purpose of producing the polyesters.

Examples of suitable diols in this connection are ethylene glycol, butylene glycol, diethylene glycol, triethylene glycol, polyalkylene glycols such as polyethylene glycol, furthermore 1,2-propanediol, 1,3-propanediol, butanediol(1,3), butanediol(1,4), hexanediol(1,6) and isomers, neopentyl glycol or hydroxypivalic acid neopentyl glycol ester or mixtures thereof, whereby hexanediol(1,6) and isomers, butanediol(1,4), neopentyl glycol and hydroxypivalic acid neopentyl glycol ester are preferred. In addition to these, polyols such as trimethylolpropane, glycerin, erythritol, pentaerythritol, trimethylolbenzene or trishydroxyethyl isocyanurate or mixtures thereof may also be employed.

By way of dicarboxylic acids in this connection, phthalic acid, isophthalic acid, terephthalic acid, tetrahydrophthalic acid, hexahydrophthalic acid, cyclohexanedicarboxylic acid, adipic acid, azelaic acid, sebacic acid, glutaric acid, tetrachlorophthalic acid, maleic acid, fumaric acid, itaconic acid, malonic acid, suberic acid, 2-methylsuccinic acid, 3,3-diethylglutaric acid and/or 2,2-dimethylsuccinic acid may be employed. The corresponding anhydrides may also be used by way of acid-source.

Provided that the mean functionality of the polyol to be esterified is ≧2, in addition monocarboxylic acids such as benzoic acid and hexanecarboxylic acid may also be used concomitantly.

Preferred acids are aliphatic or aromatic acids of the aforementioned type. Particularly preferred in this connection are adipic acid, isophthalic acid and phthalic acid.

Hydroxycarboxlyic acids that can be used concomitantly as co-reactants in the production of a polyester polyol with terminal hydroxyl groups are, for example, hydroxycaproic acid, hydroxybutyric acid, hydroxydecanoic acid or hydroxystearic acid or mixtures thereof. Suitable lactones are caprolactone, butyrolactone or homologues or mixtures thereof. Preferred in this connection is caprolactone.

Likewise, for the purpose of producing the polyisocyanate prepolymers A) polycarbonates exhibiting hydroxyl groups, for example polycarbonate polyols, preferably polycarbonate diols, may be employed. For example, such compounds with a number-average molecular weight Mₙ from ≧400 g/mol to ≦8000 g/mol, preferably ≧600 g/mol to ≦3000 g/mol, may be employed. These may be obtained by reaction of carbonic-acid derivatives, such as diphenyl carbonate, dimethyl carbonate or phosgene, with polyols, preferably diols.

Examples of diols that are suitable for this purpose are ethylene glycol, 1,2- and 1,3-propanediol, 1,3- and 1,4-butanediol, 1,6-hexanediol, 1,8-octanediol, neopentyl glycol, 1,4-bishydroxymethylcyclohexane, 2-methyl-1,3-propanediol, 2,2,4-trimethylpentanedio1-1,3, dipropylene glycol, polypropylene glycols, dibutylene glycol, polybutylene glycols, bisphenol A or lactone-modified diols of the aforementioned type or mixtures thereof.

The diol component in this connection preferably contains ≧40 percent by weight to ≦100 percent by weight hexanediol, preferentially 1,6-hexanediol and/or hexanediol derivatives. Such hexanediol derivatives are based on hexanediol and may exhibit ester groups or ether groups in addition to terminal OH groups. Derivatives of such a type are, for example, obtainable by reaction of hexanediol with excess caprolactone or by etherification of hexanediol with itself to yield dihexylene glycol or trihexylene glycol. The quantities of these and other components are chosen within the scope of the present invention in known manner in such a way that the sum does not exceed 100 percent by weight and, in particular, yields 100 percent by weight.

Polycarbonates exhibiting hydroxyl groups, in particular polycarbonate polyols, are preferably of linear structure.

Polyether polyols may likewise be employed for the purpose of producing the polyisocyanate prepolymers A). Suitable, for example, are polytetramethylene glycol polyethers such as are obtainable by polymerisation of tetrahydrofuran by means of cationic ring-opening. Likewise suitable polyether polyols may be the addition products of styrene oxide, ethylene oxide, propylene oxide, butylene oxide and/or epichlorohydrin onto difunctional or polyfunctional starter molecules. Water, butyl diglycol, glycerin, diethylene glycol, trimethyolpropane, propylene glycol, sorbitol, ethylenediamine, triethanolamine, or 1,4-butanediol or mixtures thereof, for example, may be employed as suitable starter molecules.

Preferred components for producing the polyisocyanate prepolymers are polypropylene glycol, polytetramethylene glycol polyether and polycarbonate polyols or mixtures thereof, polypropylene glycol being particularly preferred.

In this connection, polymeric polyols with a number-average molecular weight Mₙ from ≧400 g/mol to ≦8000 g/mol, preferably from ≧400 g/mol to ≦6000 g/mol and particularly preferably from ≧600 g/mol to ≦3000 g/mol, may be employed. These preferably exhibit an OH functionality from ≧1.5 to ≦6, particularly preferably from ≧1.8 to ≦3, quite particularly preferably from ≧1.9 to ≦2.1.

In addition to the stated polymeric polyols, short-chain polyols may also be employed in the production of the polyisocyanate prepolymers A). For example, ethylene glycol, diethylene glycol, triethylene glycol, 1,2-propanediol, 1,3-propanediol, 1,4-butanediol, 1,3-butylene glycol, cyclohexanediol, 1,4-cyclohexanedimethanol, 1,6-hexanediol, neopentyl glycol, hydroquinonedihydroxyethyl ether, bisphenol A (2,2-bis(4-hydroxyphenyl)propane), hydrated bisphenol A (2,2-bis(4-hydroxycyclohexyl)propane), trimethylolpropane, trimethylolethane, glycerin or pentaerythritol or a mixture thereof may be employed.

Also suitable are ester diols within the stated molecular-weight range, such as α-hydroxybutyl-∈-hydroxycaproic acid ester, ω-hydroxyhexyl-γ-hydroxybutyric acid ester, adipic acid-(β-hydroxyethyl)ester or terephthalic acid bis(β-hydroxyethyl)ester.

Furthermore, monofunctional isocyanate-reactive compounds containing hydroxyl groups may also be employed for the purpose of producing the polyisocyanate prepolymers. Examples of such monofunctional compounds are ethanol, n-butanol, ethylene glycol monobutyl ether, diethylene glycol monomethyl ether, diethylene glycol monobutyl ether, propylene glycol monomethyl ether, dipropylene glycol monomethyl ether, tripropylene glycol monomethyl ether, dipropylene glycol monopropyl ether, propylene glycol monobutyl ether, dipropylene glycol monobutyl ether, tripropylene glycol monobutyl ether, 2-ethylhexanol, 1-octanol, 1-dodecanol or 1-hexadecanol or mixtures thereof.

Furthermore, NH₂-functional and/or NH-functional components may be used for the purpose of producing the polyisocyanate prepolymers A).

Suitable components for the purpose of chain lengthening are organic diamines or polyamines. For example, ethylenediamine, 1,2-diaminopropane, 1,3-diaminopropane, 1,4-diaminobutane, 1,6-diaminohexane, isophoronediamine, isomer mixture of 2,2,4- and 2,4,4-trimethylhexamethylenediamine, 2-methylpentamethylenediamine, diethylenetriamine, diaminodicyclohexylmethane or dimethylethylenediamine or mixtures thereof are suitable.

Moreover, compounds that exhibit, in addition to a primary amino group, also secondary amino groups or, in addition to an amino group (primary or secondary), also OH groups may also be employed for the purpose of producing the polyisocyanate prepolymers A). Examples of these are primary/secondary amines, such as diethanolamine, 3-amino-1-methylaminopropane, 3-amino-1-ethylaminopropane, 3-amino-1-cyclohexylaminopropane, 3-amino-1-methylaminobutane, alkanolamines such as N-aminoethylethanolamine, ethanolamine, 3-aminopropanol, neopentanolamine. For the purpose of chain termination, use is ordinarily made of amines with a group that is reactive towards isocyanates, such as methylamine, ethylamine, propylamine, butylamine, octylamine, laurylamine, stearylamine, isononyloxypropylamine, dimethylamine, diethylamine, dipropylamine, dibutylamine, N-methylaminopropylamine, diethyl(methyl)aminopropylamine, morpholine, piperidine, or suitable substituted derivatives thereof, amide amines formed from diprimary amines and monocarboxylic acids, monoketime of diprimary amines, primary/tertiary amines, such as N,N-dimethylaminopropylamine.

The isocyanates, polyisocyanates, polyisocyanate prepolymers or isocyanate mixtures employed in A) preferably have a mean NCO functionality from ≧1.8 to ≦5, particularly preferably ≧2 to ≦3.5 and quite particularly preferably ≧2 to ≦2.5.

### Component B)

Within the scope of the present invention, component B) may in principle be a compound with at least two isocyanate-reactive amino groups. For example, component B) may be a polyamine with at least two isocyanate-reactive amino groups. In this connection, within the scope of the present invention the expression ‘isocyanate-reactive amino group’ is understood to mean an NH₂ group or NH group.

Component B) preferably is or includes an amino-functional aspartic acid ester, in particular an amino-functional polyaspartic acid ester.

Production of the amino-functional aspartic acid esters B) that are preferably employed may be effected by conversion of the corresponding primary at least difunctional amines X(NH₂)ₙ with maleic or fumaric acid esters of the general formula:

R₁OOC—CH═CH—COOR₂

Preferred maleic or fumaric acid esters are maleic acid dimethyl esters, maleic acid diethyl esters, maleic acid dibutyl esters and the corresponding fumaric acid esters. Preferred primary at least difunctional amines X(NH₂)ₙ are ethylenediamine, 1,2-diaminopropane, 1,4-diaminobutane, 1,6-diaminohexane, 2,5-diamino-2,5-dimethylhexane, 2-methyl-1,5-diaminopentane, 2,2,4- and/or 2,4,4-trimethyl-1,6-diaminohexane, 1,11-diaminoundecane, 1,12-diaminododecane, 1-amino-3,3,5-trimethyl-5-aminomethylcyclohexane, 2,4- and/or 2,6-hexahydrotoluoylenediamine, 2,4′- and/or 4,4′-diaminodicyclohexylmethane, 3,3′-dimethyl-4,4′-diaminodicyclohexylmethane, 2,4,4′-triamino-5-methyl-dicyclohexylmethane and polyetheramines with aliphatically bound primary amino groups with a number-average molecular weight Mₙ from ≧148 g/mol to ≦6000 g/mol or mixtures thereof. Particularly preferred primary at least difunctional amines are 4-diaminobutane, 1,6-diaminohexane, 2-methyl-1,5-diaminopentane, 2,2,4-trimethyl-1,6-diaminohexane or 2,4,4-trimethyl-1,6-diaminohexane or mixtures thereof.

Within the scope of a preferred embodiment of the present invention, component B) is or includes an amino-functional aspartic acid ester of the general formula (I):

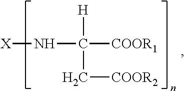

where
X stands for an n-valent organic residue that is obtained by removal of at least two primary amino groups of an n-valent amine,
R1, R2 stand for like or different organic residues that exhibit no Tserevetinov-active hydrogen, and
n stands for an integer ≧2.

X in formula (I) preferentially stands for a divalent organic residue that is obtained by removal of the amino groups from 1,4-diaminobutane, 1,6-diaminohexane, 2-methyl-1,5-diaminopentane, 2,2,4- or 2,4,4-trimethyl-1,6-diaminohexane.

The expression ‘Tserevetinov-active hydrogen’ in this connection within the scope of the present invention is understood to mean bound hydrogen which, in accordance with a process discovered by Tserevetinov, provides methane as a result of conversion with methylmagnesium iodide. In particular, within the scope of the present invention OH groups, NH groups and SH groups are understood to be groups that exhibit Tserevetinov-active hydrogen. Examples of compounds with Tserevetinov-active hydrogen are compounds that contain carboxyl, hydroxyl, amino, imino or thiol groups as functional groups.

R₁ and R₂ therefore preferentially stand for like or different organic residues that exhibit no OH, NH or SH group.

Within the scope of one embodiment of the present invention, R₁ and R₂ each stand, independently of one another, for a linear or branched alkyl group with 1 to 10 carbon atoms, particularly preferably for a methyl or ethyl group.

Within the scope of a preferred embodiment of the present invention, R₁ and R₂ stand for a ethyl group, where X is based on 2-methyl-1,5-diaminopentane by way of n-valent amine.

n in formula (I) preferably stands for the description of the valency of the n-valent amine for an integer from ≧2 to ≦6, particularly preferably ≧2 to ≦4, for example 2.

Production of the amino-functional aspartic acid esters B) from the stated initial materials may be effected in accordance with DE 693 11 633 A. Production of the amino-functional aspartic acid esters B) is preferentially effected within a temperature range from ≧0° C. to ≦100° C. In this connection the initial materials are preferentially employed in such quantitative ratios that at least one, preferentially precisely one, olefinic double bond is apportioned to each primary amino group. Subsequent to the conversion, initial materials that are optionally employed in excess can be separated off by distillation. Conversion can be effected in bulk or in the presence of suitable solvents such as methanol, ethanol, propanol or dioxan or mixtures of solvents of such a type. Catalysts may also be employed for the purpose of producing B).

Instead of the amino-functional aspartic acid esters, or in addition thereto, yet other compounds with at least two isocyanate-reactive amino groups may also be employed. Examples are aliphatic, cycloaliphatic and/or aromatic diamines or polyamines, for example 1,2-ethylenediamine, 1,2-diaminopropane, 1,3-diaminopropane, 1,4-diaminobutane, 1,6-diaminohexane, isophoronediamine, isomer mixture of 2,2,4- and 2,4,4-trimethylhexamethylenediamine, 2-methylpentamethylenediamine, diethylenetriamine, triaminononane, 1,3- and 1,4-xylylenediamine, α,α,α′,α′-tetramethyl-1,3-xylylenediamine, α,α,α′,α′-tetramethyl-1,4-xylylenediamine, 4,4-diaminodicyclohexylmethane, dimethylethylenediamine, 1-methyl-3,5-diethyl-2,4-diaminobenzene, 1-methyl-3,5-diethyl-2,6-diaminobenzene, 1,3,5-triethyl-2,6-diaminobenzene, 3,5,3′,5′-tetraethyl-4,4-diaminodiphenylmethane, 3,5,3′,5′-tetraisopropyl-4,4′-diaminodiphenylmethane, 3,5-diethyl-3′5′-diisopropyl-4,4′-diaminodiphenylmethane, polyoxyalkyleneamines (polyether amines), such as polypropylenediamine, or arbitrary mixtures of diamines of such a type or arbitrary mixtures with amino-functional aspartic acid esters. In this connection, compounds with reduced reactivity towards isocyanates are preferably employed, for example diprimary aromatic diamines, which preferably exhibit at least one alkyl group in addition to the amino groups. Examples of these are 3,5-diethyltoluoyl-2,6-diamine or 3,5-diethyltoluoyl-2,4-diamine or mixtures thereof.

The reaction mixture according to the invention for the polymer element can be obtained by mixing components A) and B). The ratio of amino groups to free NCO groups in this connection is preferentially ≧1:1.5 to ≦0.8:1, particularly preferably 1:1.

The speed at 23° C. up until an extensive crosslinking and curing of the mixture of A) and B) has been attained may typically amount to ≧1 s to ≦10 min, preferably ≧1 min to ≦8 min, particularly preferably ≧1 min to ≦5 min. Curing may be accelerated by means of catalysts. The isocyanate groups of the polyisocyanate or of the polyisocyanate prepolymer of component A) may in addition to component B)—for example, an amino-functional aspartic acid ester, a diamine and/or an NH₂-functional and/or NH-functional polyamine—also be partly converted with other compounds with isocyanate-reactive groups, for example diols or polyols. In a preferred embodiment, ≧50 mole percent of the isocyanate-reactive groups for curing component A) are amino-functional aspartic acid esters. Within the scope of a particularly preferred embodiment of the present invention, component A) is cured exclusively with amino-functional aspartic acid esters.

The reaction mixture, comprising components A) and B), may, on the one hand, be applied directly on the electrodes and cure there. On the other hand, firstly a film or a sheet may also be produced from the reaction mixture and may optionally be fully cured and subsequently combined with the electrodes. In this connection, adhesives may find application, or the adhesiveness of the reaction mixture itself may be utilised.

The reaction mixture may additionally also contain auxiliary and added substances in addition to components A) and B). Examples of such auxiliary and added substances are crosslinkers, thickeners, co-solvents, thixotroping agents, stabilisers, anti-oxidants, light-screening agents, emulsifiers, surfactants, adhesives, plasticisers, hydrophobing agents, pigments, fillers and flow-control agents.

The reaction mixture may additionally also contain fillers in addition to components A) and B). These fillers may, for example, regulate the dielectric constant of the polymer element. The reaction mixture preferentially includes fillers for the purpose of increasing the dielectric constant, such as fillers with a high dielectric constant. Examples of these are carbon black, graphite, single-walled or multi-walled carbon nanotubes or mixtures thereof. In this context, in particular such types of carbon black are of interest that exhibit a passivation and therefore do indeed increase the dielectric constant at low concentrations below the percolation threshold and nevertheless do not result in an increase in the conductivity of the polymer.

Within the scope of the present invention, additives for increasing the dielectric constant and/or for increasing the electrical breakdown field strength may still be added even after the film-formation. This can, for example, be effected by generation of a further layer (or several further layers) or by penetration of the polymer element, for example by diffusion into the polymer element.

Application of the film-forming compositions according to the invention may be effected by all forms of application known as such; mention may be made, for example, of knife coating, brushing, casting, centrifuging, spraying or extrusion.

Moreover, a multilayer application with optionally interpolated drying-steps is also possible.

Drying and fixing of the reaction mixture can be effected at temperatures of ≧30° C., preferentially from ≧10° C. to ≦200° C. In this connection a coated substrate may be conducted over a heated surface, for example a roller. Application and drying may each be carried out discontinuously or continuously. The process is preferentially entirely continuous.

The polymer element according to the invention may be provided with further layers. This may be done on one side or on both sides, in one layer or in several layers above one another, by total or by two-dimensionally partial coating of the polymer element.

Suitable as carrier materials for the production of a polymer film are, in particular, glass, release paper, sheets and plastics, from which the polymer film can optionally be simply removed.

Processing of the individual layers may be effected by casting or by knife coating, carried out manually or by machine. Printing, screen printing, injection moulding, spraying and dipping are equally possible processing techniques.

The polymer element according to the invention advantageously exhibits good mechanical strength and high elasticity. In particular, the polymer element according to the invention may exhibit a maximal stress of ≧0.2 MPa, in particular of ≧0.4 MPa and ≦50 MPa, and a maximal strain of ≧250%, in particular of ≧350%. Moreover, the polymer element according to the invention may exhibit within the strain range of use from ≧100% to ≦200% a stress from ≧0.1 MPa to ≦1 MPa, for example from ≧0.1 MPa to ≦0.8 MPa, in particular from ≧0.1 MPa to ≦0.3 MPa (determination in accordance with DIN 53504). Furthermore, in the case of a strain of 100% the polymer element according to the invention may exhibit a modulus of elasticity from ≧0.1 MPa to ≦10 MPa, for example from ≧0.2 MPa to ≦5 MPa (determination in accordance with DIN EN 150 672 1-1).

After the crosslinking, a polymer element according to the invention—taking the form of a polymer film, polymer sheet or polymer coating—may exhibit a layer thickness from ≧0.1 μm to ≦1500 μm, for example from ≧1 μm to ≦500 μm, in particular from ≧5 μm to ≦200 μm, preferentially from ≧5 μm to ≦50 μm.

The films furthermore advantageously have good electrical properties; these are determined for the breakdown field strength in accordance with ASTM D 149, and for the measurements of the dielectric constant in accordance with ASTM D 150.

For the purpose of constructing a transducer according to the invention, the polymer elements according to the invention may be coated with electrodes on both sides, as described in WO 01/06575, for example. This basic structure can be employed in the most diverse configurations for the purpose of producing sensors, actuators and/or generators.

### EXAMPLES

Unless marked otherwise, all percentage data relate to the weight.

Unless noted otherwise, all analytical measurements relate to temperatures of 23° C.

Unless expressly mentioned otherwise, NCO contents were determined volumetrically in accordance with DIN-EN ISO 11909.

The stated viscosities were determined by means of rotational viscometry in accordance with DIN 53019 at 23° C. with a rotational viscometer manufactured by Anton Paar Germany GmbH, Ostfildern, Germany.

The incorporation of fillers into the dispersions according to the invention was undertaken with a SpeedMixer (model 150 FV manufactured by Hauschild & Co KG, Postfach 43 80, Germany, 59039 Hamm).

Measurements of the film layer thicknesses were carried out with a mechanical probe manufactured by Heidenhain GmbH, Germany, Postfach 1260, 83292 Traunreut. The test specimens were gauged at three different places, and the mean value was used by way of representative measured value.

The tensile tests were performed by means of a tension-testing machine manufactured by Zwick, model number 1455, equipped with a load cell with a total measuring range of 1 kN in accordance with DIN 53 504 with a tensile-test speed of 50 mm/min. By way of test specimens, S2 tensile-test bars were employed. Each measurement was performed on three similarly prepared test specimens, and the mean value of the data obtained was used for the purpose of assessment. Specially for this purpose, in addition to the tensile strength in [MPa] and, the strain at break in [%] the stress in [MPa] at 100% and 200% strain was also determined.

The determination of the electrical volume resistivity was carried out with a measuring arrangement manufactured by Keithley Instruments Inc., 28775 Aurora Road, Cleveland, Ohio 44139, United States of America (electrometer: model number 6517A; measuring-head: model number 8009) and with a jointly supplied program (model number 6524: high-resistance measurement software). A symmetrical, rectangular voltage of +/−50 V was applied for a duration of 4 min per period for a duration of 10 periods, and the flow of current was determined. From the values for the flow of current shortly before switching the voltage, the resistance of the test piece in each period of the voltage was computed and plotted against the number of periods. The final value of this plotting indicates the measured value for the electrical volume resistivity of the specimen.

Measurements of the dielectric constant in accordance with ASTM D 150-98 were performed with a measuring arrangement manufactured by Novocontrol Technologies GmbH & Co. KG, Obererbacher Straβe 9, 56414 Hundsangen, Germany (measuring bridge: Alpha-A Analyzer, measuring-head: ZGS Active Sample Cell Test Interface) with a diameter of the test specimens of 20 mm. In this connection a frequency range from 10⁷ Hz to 10⁻² Hz was investigated. As a measure of the dielectric constant of the material being examined, the real part of the dielectric constant at 10⁻² Hz was chosen.

The determination of the breakdown field strength in accordance with ASTM D 149-97a was carried out with a high-voltage source, model LNC 20000-3pos manufactured by Heinzinger, Anton-Jakob-Str. 4 in 83026 Rosenheim, Germany, and with a specially constructed specimen-holder at the DKI (Deutsches Kunststoffinstitut, Schlolβgartenstr. 6 in 64289 Darmstadt, Germany). The specimen-holder contacts the homogeneously thick polymer specimens with only slight mechanical preloading and prevents the operator from coming into contact with the voltage. In this set-up—for the purpose of insulation against breakdowns in the air in silicone oil—the non-prestressed polymer sheet is statically loaded with increasing voltage until an electrical breakdown through the sheet occurs. The result of measurement is the voltage attained at breakdown, relative to the thickness of the polymer sheet in [V/μm].

### Substances and Abbreviations Used:

Printex 140 Product of Degussa GmbH, Weiβfrauenstr. 9, 60311 Frankfurt am Main, Germany,
   mean grain size 29 nm, BET surface area 90 m²/g, pH value 4.5 (all data on this according to the Degussa data sheet)
Härter DT Substituted aromatic diamine, NH equivalent value about 90, amine value about 630 mg KOH/g, viscosity about 200 mPas.

### Application-Oriented Tests

### Example 1

### Prepolymer A-1

840 g hexamethylene diisocyanate (HDI) and 0.08 g zinc octoate were charged in a 4 litre four-necked flask. Within one hour, 1000 g of a difunctional polypropylene glycol po 1 yether with a molar mass of 8000 g/mol were added at 80° C. and were stirred further for one hour. Then 0.3 g benzoyl chloride were added. Subsequently the excess HDI was distilled off by thin-layer distillation at 130° C. and at 0.1 ton. A prepolymer with an NCO content of 1.80% was obtained.

### Example 2

### Prepolymer A-2

840 g toluoylene diisocyanate (TDI) and 0.08 g zinc octoate were charged in a 4 litre four-necked flask. Within one hour, 1000 g of a difunctional polypropylene glycol polyether with a molar mass of 8000 g/mol were added at 80° C. and stirred further for one hour. Then 0.3 g benzoyl chloride were added. Subsequently the excess TDI was distilled off by thin-layer distillation at 130° C. and at 0.1 torn A prepolymer with an NCO content of 1.66% was obtained.

### Example 3

### Aspartate B

To 2 mol diethyl maleate under nitrogen atmosphere 1 mol 2-methyl-1,5-diaminopentane was slowly added dropwise in such a way that the reaction temperature did not exceed 60° C. Subsequently heating to 60° C. was effected for such time until no diethyl maleate could any longer be detected in the reaction mixture.

### Example 4

### According to the Invention

The raw materials employed were not separately degassed. The requisite quantities of 2 g of Aspartate B from Example 3 and 20.79 g Prepolymer A-2 from Example 2 were weighed into a polypropylene beaker and mixed in the SpeedMixer at 3000 revolutions per minute for 2 s. From the still liquid reaction mixture, films with a wet-film thickness of 1 mm were knife-coated by hand onto glass plates. After production, all the films were dried overnight at 80° C. in a drying cabinet and were subsequently after-annealed for 5 min at 120° C. The films were able to be easily detached from the glass plate by hand after the annealing.

### Example 5

### According to the Invention

The raw materials employed were not separately degassed. The requisite quantities of 2 g of Härter DT and 71.99 g Prepolymer A-2 from Example 2 were weighed into a polypropylene beaker and mixed in the SpeedMixer at 3000 revolutions per minute for 2 s. From the still liquid reaction mixture, films with a wet-film thickness of 1 mm were knife-coated by hand onto glass plates. After production, all the films were dried overnight at 80° C. in a drying cabinet and were subsequently after-annealed for 5 min at 120° C. The films were able to be easily detached from the glass plate by hand after the annealing.

### Example 6

### According to the Invention

The raw materials employed were not separately degassed. The requisite quantities of 0.5 g of Härter DT, 0.5 g Aspartate B from Example 3 and 18.07 g Prepolymer A-1 from Example 1 were weighed into a polypropylene beaker and mixed in the SpeedMixer at 3000 revolutions per minute for 2 s. From the still liquid reaction mixture, films with a wet-film thickness of 1 mm were knife-coated by hand onto glass plates. After production, all the films were dried overnight at 100° C. in a drying cabinet and were subsequently after-annealed for 5 min at 120° C. The films were able to be easily detached from the glass plate by hand after the annealing.

### Example 7

### Comparative Example

All the liquid raw materials were carefully degassed under argon in a three-stage process, the carbon black was sieved through a 125 μm sieve. 10 g Terathane 650 (INVISTA GmbH, D-65795 Hatterheim, poly-THF with a molar mass Mn=650) were weighed with 0.596 g carbon black (Ketjenblack EC 300 J, product of Akzo Nobel AG) into a 60 ml single-use mixing vessel (APM-Technika AG, Order No. 1033152) and mixed in the SpeedMixer (Product of APM-Technika AG, 9435 Heerbrugg, Switzerland; marketing D: Hauschild; type DAC 1 50 FVZ) for 3 min at 3000 revolutions per minute to yield a homogeneous paste. Subsequently 0.005 g dibutyltin dilaurate (Metacure® T-12, Air Products and Chemicals, Inc.) and 6.06 g of Isocyanate N3300 (the isocyanurate trimer of HDI; product of Bayer MaterialScience AG) were weighed in and mixed in the SpeedMixer for 1 min at 3000 revolutions per minute. The reaction paste was poured onto a glass plate and drawn out with a knife with a wet-film thickness of 1 mm into a homogeneous film with a solids content of 2%. The film was subsequently annealed for 16 h at 80° C.

### Example 8

### Comparative Example

All the liquid raw materials were carefully degassed under argon in a three-stage process. 10 g Terathane 650 (INVISTA GmbH, 65795 Hatterheim, Germany, poly-THF with a molar mass Mn=650) were weighed into a 60 ml single-use mixing vessel (APM-Technika AG, Order No. 1033152). Subsequently 0.005 g dibutyltin dilaurate (Metacure® L-12, Air Products and Chemicals, Inc.) and 6.06 g of Isocyanate N3300 (the isocyanurate trimer of HDI; product of Bayer MaterialScience AG) were weighed in and mixed in the SpeedMixer for 1 min at 3000 revolutions per minute. The reaction product was poured onto a glass plate and drawn out with a knife with a wet-film thickness of 1 mm into a homogeneous film. The film was subsequently annealed for 16 h at 80° C.

### Example 0.9

### Comparative Example

All the liquid raw materials were carefully degassed under argon in a three-stage process, the carbon black was sieved through a 125 μm sieve. 10 g Terathane 650, (INVISTA GmbH, 65795 Hatterheim, Germany, poly-THF with a molar mass Mn=650) was weighed with 0.536 g Printex 140 into a 60 ml single-use mixing container (APM-Technika AG, Order No. 1033 1 52) and mixed in the SpeedMixer (product of APM-Technika AG, 9435 Heerbrugg, Switzerland; marketing D: Hauschild; type DAC 150 FVZ) for 3 min at 3000 revolutions per minute to yield a homogeneous paste. Subsequently 0.005 g dibutyltin dilaurate (Metacure® T-12, Air Products and Chemicals, Inc.) and 6.06 g of Isocyanate N3300 (the isocyanurate trimer of HDI; product of Bayer MaterialScience AG) were weighed in and mixed in the SpeedMixer for 1 min at 3000 revolutions per minute. The reaction paste was poured onto a glass plate and drawn out with a knife with a wet-film thickness of 1 mm into a homogeneous film with a solids content of 2%. The film was subsequently annealed for 16 h at 80° C.

TABLE 1
Properties of the films produced in Examples 4 to 9

| | | | Stress at | Stress at | Electrical | | Breakdown |
|---|---|---|---|---|---|---|---|
| | Strain at | Tensile | 100% | 200% | volume | | field |
| | break | strength | strain | strain | resistivity | Dielectric | strength |
| Example | [%] | [MPa] | [MPa] | [MPa] | [ohm cm] | constant | [V/μm]] |
| 4* | 288 | 1.1 | 0.47 | 0.48 | 1.9 · 10¹¹ | 25.0 | 25 |
| 5* | 253 | 3.8 | 1.60 | 3.00 | 2.6 · 10¹² | 9.0 | 29 |
| 6* | 316 | 2.1 | 0.87 | 1.36 | 1.9 · 10¹¹ | 36.6 | 32 |
| 7 | 57 | 3.4 | — | — | 6.4 · 10¹¹ | 28.4 | 7 |
| 8 | 44 | 1.7 | — | — | 2.7 · 10¹² | 18.6 | 11 |
| 9 | 46 | 1.6 | — | — | 7.9 · 10¹¹ | 550.0 | 5 |

*according to the invention

It was evident in the tests that the films according to the invention offer clear advantages in comparison with the state of the art. In particular, for the films according to the invention that are formed from aspartic acid esters and polyisocyanate prepolymers these advantages were able to be increased further.

Particularly advantageous with the use of the films according to the invention are the high dielectric constant with, at the same time, very high breakdown field strength in the unstrained state, in particular in the particularly preferred embodiments of the films according to the invention formed from aspartic acid esters and polyisocyanate prepolymers, and the very good mechanical properties, such as high elasticity, high elongation at break, well-suited stress-strain curve with low stress at moderate strains within the range of use of the application. In particular, the strain at break and the strain behaviour, in addition to the high dielectric constant, were able to be increased further with, at the same time, very high breakdown field strength in the unstrained state in the particularly preferred embodiments of the films according to the invention formed from aspartic acid esters and polyisocyanate prepolymers. In the comparative examples a stress at 100% or 200% was not measurable, since these materials already tore at 40% to 60%.

1. An electromechanical transducer comprising at least two electrodes and at least one polymer element, the polymer element being arranged between two electrodes,
wherein
the polymer element is the reaction product of
A) one selected from the group consisting of a polyisocyanate, a polyisocyanate prepolymer and a mixture thereof, and
B) a compound with at least two isocyanate-reactive amino groups.

2. The electromechanical transducer according to claim 1, wherein the electromechanical transducer comprises one or more of a sensor, an actuator and a generator.

3. The electromechanical transducer according to claim 1, wherein component
A) is selected from the group consisting of a polyisocyanate containing isocyanurate groups, a polyisocyanate containing urethane groups, a polyisocyanate prepolymer containing isocyanurate groups, a polyisocyanate prepolymer containing urethane groups and a mixture thereof.

4. The electromechanical transducer according to claim 1, wherein component
B) is an amino-functional aspartic acid ester.

5. The electromechanical transducer according to claim 1, wherein component
B) is an amino-functional aspartic acid ester of the general formula (I): 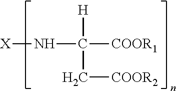
wherein
X is an n-valent organic residue obtained by removal of at least two primary amino groups from an n-valent amine,
R₁, R₂ are like or different organic residues that contain no Zerewitinov-active hydrogen, and
n is an integer ≧2.

6. The electromechanical transducer according to claim 1, wherein component
B) is an amino-functional aspartic acid ester of the general formula (I): 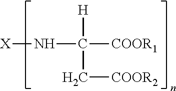
wherein
X is a divalent organic residue obtained by removal of amino groups from 1,4-diaminobutane, 1,6-diaminohexane, 2-methyl-1,5-diaminopentane, 2,2,4- or 2,4,4-trimethyl-1,6-diaminohexane,
R₁, R₂ each are, independently, a linear or branched alkyl group with 1 to 10 carbon atoms, and
n is 2.

7. A process for producing the electromechanical transducer according to claim 1 comprising:
providing at least two electrodes
providing a polymer element comprising the reaction product of:
A a polyisocyanate or a polyisocyanate prepolymer or a mixture thereof,
and
B) a compound with at least two isocyanate-reactive amino groups,
and
arranging the polymer element between the two electrodes.

8. The process according to claim 7, wherein that the polymer element is applied as a reaction mixture onto at least one of the electrodes.

9. The process according to claim 7, further including drying and/or annealing the reaction mixture.

10. An electromechanical element comprising polymer element comprising the reaction product of
A) one selected from the group consisting of a polyisocyanate, polyisocyanate prepolymer and a mixture thereof, and
B) a compound with at least two isocyanate-reactive amino groups.

11. One of an electronic or electrical apparatus including the electromechanical transducer according to claim 1.

12. (canceled)
